(19) United States
(12) Patent Application Publication
(10) Pub. No.: US 2011/0277681 A1
(43) Pub. Date: Nov. 17, 2011

(54) GAS INJECTORS FOR CVD SYSTEMS WITH THE SAME

(76) Inventors: Chantal Arena, Mesa, AZ (US); Ronald Thomas Bertram, JR., Mesa, AZ (US); Ed Lindow, Scottsdale, AZ (US)

(21) Appl. No.: 13/145,290

(22) PCT Filed: Feb. 17, 2010
(86) PCT No.: PCT/US2010/024374

§ 371 Date: Jul. 19, 2011

Related U.S. Application Data
(60) Provisional application No. 61/157,112, filed on Mar. 3, 2009.

(51) Int. Cl. C30B 23/06; F16K 49/00; C23C 16/34

(52) U.S. Cl. 117/88; 118/724; 118/719; 137/334

(57) ABSTRACT

The present invention provides improved gas injectors for use with chemical vapour deposition (CVD) systems that thermalize gases prior to injection into a CVD chamber. The provided injectors are configured to increase gas flow times through heated zones and include gas-conducting conduits that lengthen gas residency times in the heated zones. The provided injectors also have outlet ports sized, shaped, and arranged to inject gases in selected flow patterns. The invention also provides CVD systems using the provided thermalizing gas injectors. The present invention has particular application to high volume manufacturing of GaN substrates.

### FIELD OF THE INVENTION

The present invention relates to semiconductor processing equipment, and in particular, provides gas injectors that inject thermalized gases into CVD chambers, and injectors that inject thermalized gases in pre-determined flow patterns. The present invention also provides CVD systems using the provided gas injectors. The invention has particular application to high volume manufacturing of GaN substrates.

### BACKGROUND OF THE INVENTION

Inadequate thermalization (heating) of precursor gases prior to their injection into a CVD chamber and their premature mixing within the chamber can lead to a number of problems that can be specific to each particular CVD process being performed. Consider, as an example, the hydride-vapour-phase epitaxial (HVPE) growth of GaN using GaCl₃, and NH₃ as the precursor gases, where problems caused by inadequate thermalization and premature mixing include the following.

First, injection of inadequately thermalized precursors can lead to unwanted deposition on surfaces other than the growth substrate. Over time this unwanted material can lead to increased particulate levels in the reactor sufficient to decrease wafer quality, and also to coating of chamber walls sufficient to interfere with efficient radiant heating. Such undesirable deposition occurs since GaCl₃ condenses from the vapour phase at relatively low temperatures, e.g., less than 500° C., and therefore areas of the reactor which are not maintained above vaporization temperatures are likely to become coated. It is therefore desirable that GaCl₃ be thermalized to temperatures of at least about 500° C. prior to injection into reaction chamber. In fact, it is desirable to thermalize the GaCl₃ precursor to temperatures of at least 730° C. prior to injection into reaction chamber.

Further in connection with HVPE processes, injection of inadequately thermalized precursors can lead to unwanted side reactions that limit actual GaN deposition. Because gas temperatures less than about 930° C. can lead to formation of undesirable adducts, e.g., GaCl₃:NH₃, it is also desirable that both GaCl₃ and NH₃ be thermalized to a temperature of at least about 930° C. prior to injection into the reaction chamber. Moreover, to further limit formation of such undesirable adducts, it is preferable to keep separate the group III and group V precursor flows until they are in the direct vicinity of the growth susceptor. Premature mixing of the precursor gases can result in unwanted reaction by-products and the production of particulates within the reactor.

Finally in connection with HVPE processes, it is desirable to thermalize the group V precursor (commonly NH₃) prior to injection into the reaction chamber. Inadequately thermalized group V precursor, upon mixing with a thermalized group III precursor, can cool the group III to a sufficient extent to lead to the above undesirable effects. However, thermalization of the group V ammonia precursor should not be carried out in an environment containing metals, e.g., in metallic gas lines, metallic reactor components, etc., as is often done. At elevated temperatures, metals can catalyze cracking of reactive NH₃ to N₂ (and H₂) which is not reactive with GaCl to produce GaN.

The above problems resulting from inadequate thermalization and premature mixing result in an inefficient reaction of the precursor gases to form the GaN product at the substrate. Precursor reactants are lost due to particle/complex formation, deposition on unwanted surfaces, and so forth. Improving thermalization and delivery of precursor gases can be expected to result in a more efficient utilization of precursor gases with the associated benefits in reduced costs and improvements in material growth rate.

Problems of precursor thermalization and separation for HVPE III-nitride deposition is addressed in U.S. Pat. Nos. 6,179,913, 6,733,591. However, this prior art is concerned with conventional equipment where GaCl is formed in situ by reacting HCl gas with liquid gallium and is not applicable to equipment that directly injects gaseous GaCl₃. U.S. provisional application 60/015,524 is concerned with thermalization and spatial separation of precursors utilizing external GaCl₃ and NH₃ sources, however this prior art application utilizes a single injection fixture for injection of both the group III and group V precursors.

### SUMMARY OF THE INVENTION

To overcome the limitations of the prior art the present invention provides a number of elements, including thermalizing gas injectors, for improving precursor thermalization and mixing, features previously noted to be advantageous.

The thermalizing gas injectors of this invention provide better precursor thermalization by conducting gases through conduit structures that are sized and configured to increase the residence times of conducted gases, and at the same time, by providing heating means that passively or actively heat the conduit structures. Generally, since residence time is the ratio of gas flow length to gas flow velocity, different embodiments of this invention can provide conduit structures that are configured and sized to either increase or decrease, or to leave unchanged, the gas flow path lengths and gas flow velocities as long as their ratio, the residence time, is increased. In preferred embodiments, only one of these parameters is significantly changed while the other is left substantially unchanged. In particular, certain preferred embodiments have conduit structures configured and sized to have a longer path length with a cross-section sufficient to preserve flow velocities, or to have increased cross section (and correspondingly decreased gas velocities) with a substantially unchanged path length.

Relative terms, e.g., “increased”, “decreased”, and “unchanged”, as applied to a conduit of the invention, are to be understood as in comparison to a conduit that would by typically used to convey the same selected quantities of gases between the same gas sources and gas sinks. Typical conduits are usually as short as reasonably allowed in view of obstructions between source and sink, design criteria, safety, and the like. However, embodiments of this invention have conduits that are longer than such reasonable minimum lengths. Also, typical conduits usually have a cross section as small as reasonably allowed in view of the required mass flow, gas properties, and so forth. Similarly, embodiments of this invention include conduits with cross sections that are larger than such reasonable minimum cross sections.

The invention includes specific preferred thermalizing injectors, each satisfying a specific gas injection requirement (and suitable for a specific CVD chamber). For example, for injecting gases at relatively higher flow rates, suitable embodiments can have wider and/or shorter gas-conducting conduits, while conversely, for injecting gases at relatively lower flow rates, suitable embodiments can have narrower and/or longer gas-conducting conduits. Also, for injecting gas streams with selected cross-sectional profiles, suitable embodiments can have exit ports configured similarly to the selected cross sectional profile. Gas streams with smaller cross-sectional profile can be injected though nozzle-like exit ports, while gas streams with larger cross sectional profiles, e.g., profiles that extend across a significant portion of a CVD chamber, can be injected through a horizontally-wide but vertically-narrow exit port. Also, for injecting gases that can benefit from increased thermalization, suitable embodiments can have gas conduits with even longer residence times, e.g., conduits that are longer, or that have larger cross sections, or both. Further, conduit structures and gas flow paths can have different portions with different combinations of cross sectional size and length, or with smoothly varying cross-sectional sizes, or the like, as long as the net effect is increased residence times. However, it should be understood that such specific embodiments can be useful with a wide for gases having a wide variety of other and different injection requirements.

Conduit structures and components, e.g., gas-conducting portions, are preferably fabricated from materials capable of withstanding high temperature, corrosive environments, but also of being formed into required shapes at lower cost. A preferred material comprises quartz.

Heating means for conduit structures can be active or passive. Active heating means include heat producing elements, e.g., resistive elements, radiant elements, microwave elements, and so forth, specifically selected and positioned, usually adjacent, so as to transfer heat directly to the conduit structures. Passively heating refers to conduits located at least partly in a heated environment, e.g., CVD chamber, from which heat can be absorbed. Heated environments are often heated by active heating means, and conduit structures are preferably positioned in such environments with respect to such active heating means so that heat transfer is optimized in the circumstances. For example, in case of a CVD chamber heated by radiant elements, a conduit structure can be positioned near, or with an unobstructed path to, the radiant elements, but so that susceptors, robot arms, and the like, are not interfered with. Passive heating can also be optimized by including structures that absorb heat from the environment so as to transfer it to the conduit structures. Additionally, passive heat transfer means can include black body structures positioned to absorb and re-radiate radiant energy to the conduit structure.

Black body structures are preferably fabricated from materials with emissivity values close to unity (at least for infrared radiation) and that are also capable of withstanding high temperature, corrosive environments. Suitable materials include AlN, SiC and B₄C (having emissivity values of 0.98, 0.92, 0.92, respectively).

Preferred embodiments of the invention provide injectors for injecting gases into CVD (chemical vapour deposition) chambers. The injectors include one or more gas-conducting conduits for conveying gases along a flow path through the conduit from a gas inlet port to one or more gas outlet ports; the conduits have one or more segments configured and/or sized to increase the times required for gases to flow through the conduit in comparison to the times required were the selected segment not so configured and sized. Preferably, at least part of the gas-conducting conduits is of quartz. The preferred embodiments of the invention also provide heating means for heating the conduits including a heated CVD chamber, or one or more heat-producing elements, or similar. Preferred uses of the injectors of the invention include injecting precursor gases and/or purge gases for conducting CVD processes; for example, the precursor gases can include III-metal precursors or nitrogen precursors for growth of a III-nitride semiconductor in the CVD chamber.

In preferred embodiments, the provided injectors have gas-conducting conduits that include at least one segment configured to have a longer gas flow path, so that gas flow times are increased without decreases in gas flow velocities. The longer segments can be configured to have a spiral-like shape that lengthens the gas flow path between entry and exit. The conduits can also include an outer housing which encloses part of all or the spiral-shaped segment; the outer housing can be provided with external clamp-shell heaters arranged adjacent to the outer housing, or with interior black body elements external to the spiral-shaped segment that enhance heat transfer from the exterior to the gas-conducting conduit; the outer housing can also have a gas inlet port and a gas outlet port that can be configured and sized so that gases can flow through the inner housing from the inlet port to the and outlet port.

In preferred embodiments, the provided injectors have gas-conducting conduits that include at least one segment configured to have a gas flow path with a larger cross-section size so that gas flow times are increased with decreases in gas flow velocities. The larger segments can be of larger but substantially constant cross section; the larger segments can be configured and sized to be arranged within a CVD chamber where they can be heated by the CVD chamber (when heated); the larger, interior segments of such injectors can be further arranged along a longitudinal interior wall of the chamber; the larger, lateral of such injectors segments can have a plurality of outlet ports arranged to direct gas flows from the lateral wall towards the centre of the chamber.

In preferred embodiments, the provided injectors with conduits having a larger cross-section sizes can be configured so that the cross-section sizes grow larger from an apex portion where gases enter the conduit towards a base portion where gases leave the conduit and enter the CVD chamber; the larger segments can be configured to have a relatively narrower apex with one or more gas inlet ports and a relatively broader base with one or more gas outlet ports that open into the CVD chamber; the larger segments can be configured as a wedge-shaped channel within a planar structure. The planar structure can be configured to be shorter in a vertical direction and larger in a transverse direction; the planar structure can be configured and sized to be arranged interior to the CVD chamber where it can be heated by the CVD chamber (when heated); in particular, the planar structure can be positioned along an upstream transverse chamber wall so as to direct exiting gas in a downstream direction; the planar structure can also include one or more second gas-conducting conduits that do not intersect the wedge-shaped channel. The second gas-conducting conduits can have substantially constant cross-section sizes, and can have one or more second outlet ports that open into the CVD chamber laterally to the outlet port of the wedge-shaped channel.

The invention also provides CVD systems with one or more of the provided gas injectors. Such a system can include one or more first injectors of the embodiments having a conduit configured and sized to grow larger from an apex portion towards a base portion; this injector can have an outlet port adjacent to a susceptor having a growth surface within the CVD chamber and can be oriented to direct first gases in a longitudinal flow that extends transversely across a portion or all of the susceptor growth surface; this injector can include second conduits with two or more second outlet ports oriented to direct second gases in longitudinal flows lateral to the first gas flow.

Such a system can also include one or more second injectors of the embodiments having a conduit configured into a spiral-like shape; this injector can have outlet ports positioned and arranged to direct gases into the inlet ports of the first injectors.

Such a system can also include one or more third injectors of the embodiments having a segment configured with a larger cross-sectional size; this injector can be configured and sized so that the larger segment can be arranged interior to a CVD chamber wherein it can be heated by the CVD chamber (when heated); the larger interior segment can be arranged along a longitudinal interior wall of the chamber; this larger segment can have a plurality of outlet ports positioned and oriented to direct multiple gas flows from the lateral wall towards the center of the chamber. Such a system can also include one or more black body plates for enhancing heat transfer from heating elements external to the CVD chamber to the third injectors.

Another embodiment of the invention relates to a method for injecting gases into a CVD (chemical vapour deposition) chamber by conveying gases along a segmented flow path from a gas inlet port to one or more gas outlet ports, with each segment configured or sized to increase gas flow time in comparison to the segments that are not so configured and sized; and heating the one or more segments as the gases are conveyed therethrough. The at least one selected segment provides a gas flow path with a larger cross-section size and increased gas flow times at smaller gas flow velocities with the gases flowing therein including a nitrogen precursor for growth of a Group III-nitride semiconductor in the chamber. Also, at least one other segment has a cross-sectional size that grows larger from an apex section towards a base section where the segment opens into the chamber, with the gases flowing therein including a Group III-metal precursor for growth of a Group III-nitride semiconductor in the chamber. The chamber preferably includes therein a susceptor having a growth surface and the gases of Group III-metal and nitrogen precursors are heated and directed toward the susceptor growth surface for growth of a Group III-nitride semiconductor thereon. Advantageously, the gases react at a temperature approximately greater than 930° C. to facilitate growth of Group III-nitride semiconductor on the susceptor growth surface while minimizing formation of undesirable precursor complexes.

The preferred embodiments and particular examples described herein should be seen as examples of the scope of the invention, but not as limiting the present invention. The scope of the present invention should be determined with reference to the claims, which are to be interpreted as covering modifications, equivalents, alternatives, and the like, apparent to artisans of ordinary skill in the art. For clarity and conciseness, not all features of the embodiments are described here; it will be understood that features not described are routine in the art and could be added by an artisan of ordinary skill.

Headings are used herein for clarity only and without any intended limitation. A number of references are cited herein, the entire disclosures of which are incorporated herein, in their entirety, by reference for all purposes. Further, none of the cited references, regardless of how characterized, is admitted as prior to the invention of the subject matter claimed herein.

### BRIEF DESCRIPTION OF THE DRAWINGS

The present invention may be understood more fully by reference to the following detailed descriptions of the preferred embodiments and illustrative examples of specific embodiments of the present invention, and the appended figures in which:

FIG. 1 schematically illustrates an exemplary CVD reactor;

FIGS. 2A-D schematically illustrate a first embodiment of the thermalizing gas injectors of this invention;

FIGS. 3A-C schematically illustrate a second embodiment of the thermalizing gas injectors of this invention;

FIGS. 4A-C schematically illustrate a third embodiment of the thermalizing gas injectors of this invention; and

FIG. 5 schematically illustrates a combination including the exemplary CVD chamber and the thermalizing gas injectors of this invention

### DETAILED DESCRIPTION OF THE PREFERRED EMBODIMENTS

The present invention provides improved gas handling for chemical vapour deposition (CVD) reactors systems, especially CVD systems used for semiconductor processing and more especially CVD systems having chambers with generally rectangular cross-sections in which a planar flow of precursor gases crosses a substrate at which deposition or other reactions take place. Exemplary CVD chambers in which the invention can be usefully applied are briefly described before turning to the invention.

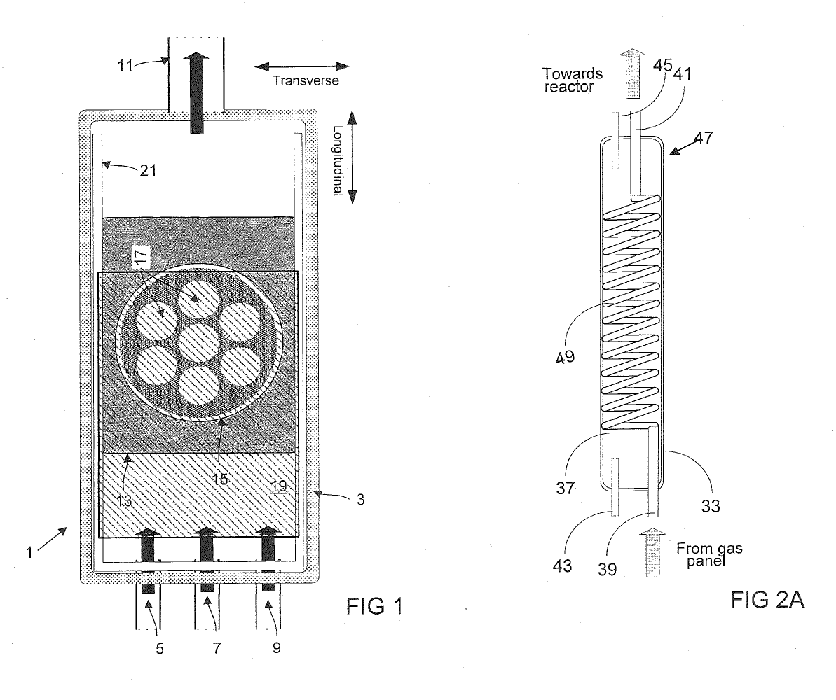

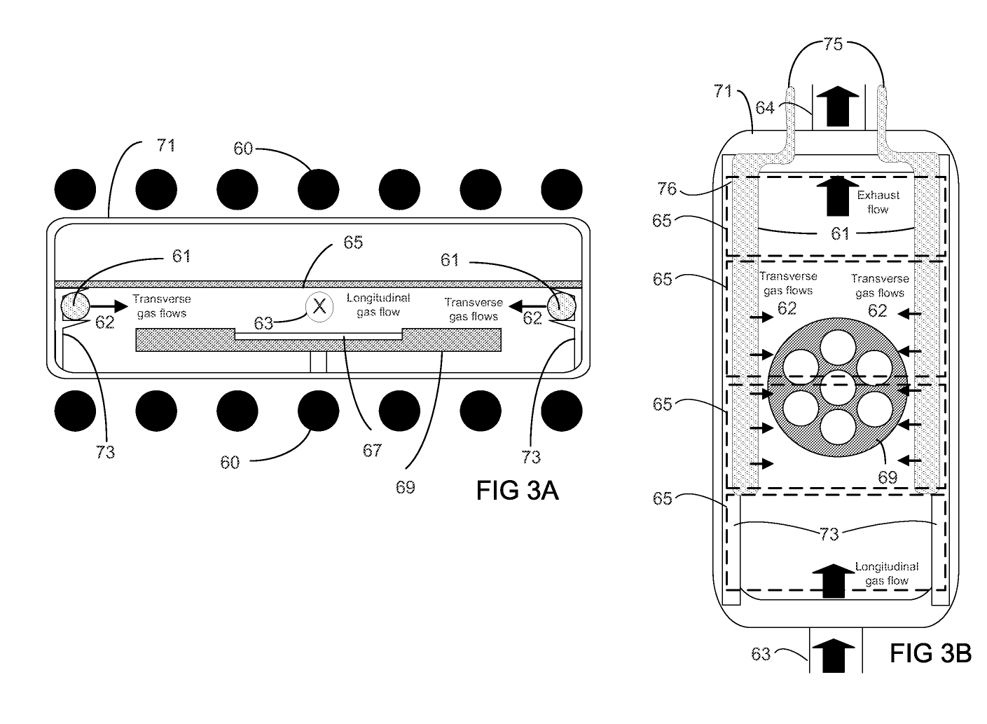

FIG. 1 illustrates in plan view relevant detail of exemplary CVD chamber 1 to which this invention is applicable. FIG. 3A illustrates in cross-section view a similar CVD reactor. Common reference numbers identify similar elements in both figures. Exemplary reactor 1 includes reactor chamber 3 which is usually made of quartz so that it can be heated by external, radiant heating lamps. Process gases including precursor gases and purge gases enter chamber 3 at the bottom of the figure through ports (or inlets or injectors) 5 and 9. The inlet ports are commonly designed and arranged to prevent premature mixing of the precursor gases. Here, for example, different precursor gases can enter through spaced-apart ports 5 and 9, while relatively inert purge gases can enter through port 7. The process gases then travel upward in the figure through the chamber (defining the ‘downstream’ direction) and react at centrally-located substrates supported by substrates 17 on susceptor 15. The susceptor usually rotates guided by support ring or plate 13. The process gases exit the chamber through exhaust 11.

Optionally, reactor 1 can include black body plate 19 supported on, e.g., support 21, above susceptor 15 and substrates 17. This black body plate can aid in thermalizing process gases flowing in proximity to the plate by absorbing radiation from radiant heat lamps, and reradiating the absorbed radiation into process gases. See, e.g., U.S. provisional patent application 61/031,837 filed Feb. 27, 2008 (which is incorporated herein by reference in its entirety for all purposes).

In the following, the terms “longitudinal” and “transverse” are used to refer to the directions within a CVD chamber indicated by the labelled arrows in FIG. 1. Longitudinal directions are also referred to as “upstream” and “downstream”; the longitudinally oriented walls are also referred to as side (or lateral) walls. Transverse directions are also referred to as “across the reactor”; the transversely oriented walls are also referred to as end walls.

The invention is described in the following in the context of this exemplary CVD chamber, the details of which are not further considered. However, the focus is for conciseness only and without limitation, as it will be understood that this exemplary chamber is not limiting, and that the apparatus of the invention is compatible with other CVD chambers.

### Preferred Embodiments of Thermalizing Gas Injectors

Preferred embodiments of the thermalizing gas injectors of this invention are now described that achieve increased gas residence times by configuring and sizing conduit structures to have gas flow paths with lengths that are increased beyond those reasonably necessary in the circumstances (in view of the physical layout of the chamber and associated equipment) and that have cross sections that are at least not substantially less than what is reasonably necessary for the intended gas flow velocities (in view of known principles of gas flow in conduits). Accordingly, the injectors of this embodiment can be useful for gases that enter into the CVD chamber at relatively lower flow rates. Preferably, increased path length can be accommodated by bending and/or folding the flow path into serpentine shape, e.g., a spiral shape.

Since thermalizing gas injectors of this embodiment are useful for injecting better thermalized gases at relatively lower, or at least not increased, flow rates, when used in connection with the growth of III-nitride compounds, the injectors of this embodiment are more preferred for use with III-metal precursors, which typically enter at relatively lower flow rates, than for use with for N precursors, which typically enter at relatively higher flow rates. However, the injectors of this embodiment can also be useful for gases that enter into the CVD chamber at relatively lower flow rates.

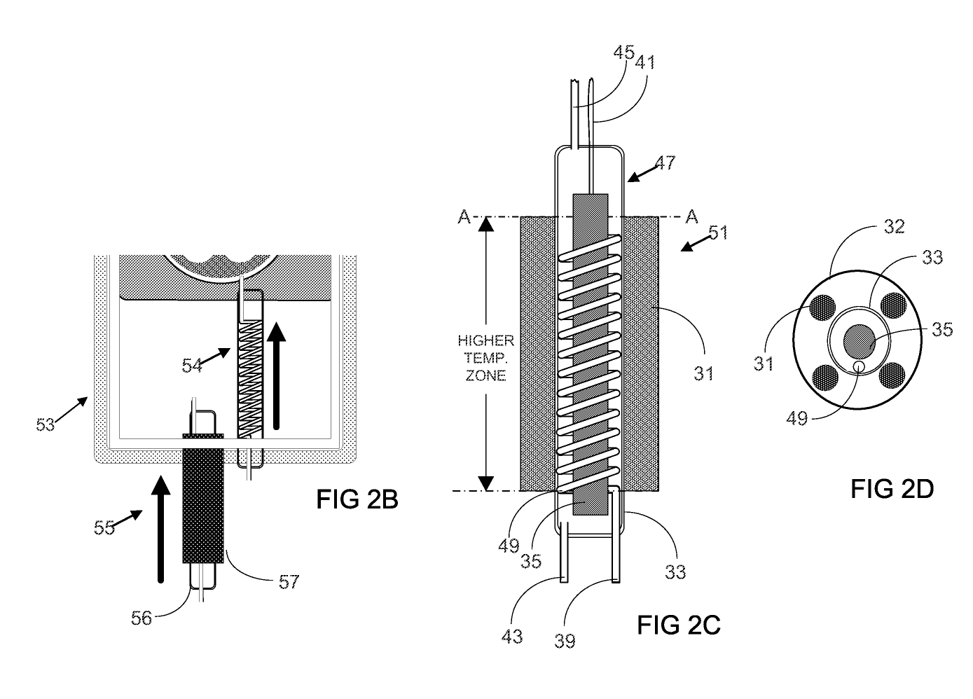

FIGS. 2A-D illustrate thermalizing gas injectors of this embodiment. In particular, FIG. 2A illustrates conduit structure 47 with spiral-shaped, gas-conducting conduit 49 with a substantially uniform diameter (cross-section). Gases, e.g., precursor gases, enter into conduit structure 47 through inlet port 39, flow through spiral-shaped gas-conducting portion 49, and exit from the conduit structure through outlet 41, e.g., directly into a CVD chamber. Gas-conducting conduit 49 provides a gas path length that is substantially longer than reasonably necessary to conduct gases over the shorter, physical distance between inlet port 39 and outlet port 41. Because of the spiral shape of gas-conducting conduit 49, the path length of gas flowing through conduit structure 47 is longer, even substantially longer, than the actual physical distance between the inlet and outlet ports. The spiral-shaped illustrated here is not limiting, and the invention should be understood to include other serpentine shapes. Precursor gases can be supplied to conduit structure 47 from external sources at flow rates controlled by an external gas control arrangement (“a gas panel”).

Conduit structures of this embodiment preferably include outer housings that enclose and protect at least the serpentine-shaped portions of the gas-conducting conduits (which are expected to be easily damaged). Here, conduit structure 47 includes outer housing 33 enclosing all of gas-conducting portion 49 other than inlet port 39 and outlet port 41. Outer-housings can also serve as additional gas-conducting conduits for, e.g., purge gases. Here, outer housing 33 has been provided with purge-gas inlet port 43 and purge-gas outlet port 45 so that a purge gas can flow through the outer housing. Purge gas (or similar gas) flows are advantageous since they can form regions of overpressure with respect to the CVD chamber interior that can act to limit or prevent back flows of gases from the chamber interior. Back flows of reactive and often corrosive gases from the interior of an operating CVD chamber can cause damage to, or undesirable deposition on, a conduit structure.

Conduit structure 47 can be passively heated, or actively heated, or both passively and actively heated. Conduit structures are passively heated preferably by being partially or entirely located within a heated CVD chamber (or within another heated environment). FIG. 2B illustrates passively-heated conduit structure 54 (similar to that of FIG. 2A) located largely with CVD chamber 53. Passive heat-transfer elements (not illustrated here) can be optionally provided to improve transfer of heat from the chamber interior to the conduit structure. For example, if the CVD chamber is heated by heat lamps, a passive element can include a black body structure located in the vicinity of the gas injector that absorbs radiation from the heat lamps and re-radiates it to the conduit structure.

Conduit structures are preferably actively heated by providing heat producing elements that are adjacent to at least a portion of the gas-conducting portion, preferably at least part of which is configured for increased gas residence times, and that provide heat directly to the adjacent portion. Actively heating elements are preferably located adjacent (or near) and exterior to the conduit structure; they can also be located interior to the conduit structure. Active heating elements include radiation emitting elements, e.g., heat lamps, inductive heating elements, electrical heating elements, e.g., resistance heating elements, and so forth. Conduit structures can also be both passively and actively heated, for example, when an actively heated conduit structure is located at least partially within a CVD.

FIG. 2B illustrates actively-heated gas injector 55 located largely external to CVD chamber 53 (similar to CVD chamber 1 of FIG. 1). Injector 55 includes gas-conducting portion 56 and active heating elements 57. In further embodiments of the invention actively-heated gas injector 55 can be external to CVD chamber 53 and located beneath the reactor with heated precursor input 41 entering into the underside (i.e. into the base) of the CVD chamber.

FIGS. 2C-D illustrate essential details of actively heated conduit structure 51. In FIG. 2C (plan view), active heating element 31 comprises a conductive element, e.g., a resistively heated clamp-shell heater, located exterior to and about outer housing 33. In FIG. 2D (cross section view), active heating elements 31 comprise radiant elements, e.g., heat lamps, that are external to outer housing 33 of the conduit structure but which are enclosed within shell 32, which can serve to reflect radiation inwards to gas-conducting conduit 49. In both figures, gases flowing through spiral-shaped, gas-conducting conduit 49 from inlet 39 to outlet 41 are heated by heating element 31 before injection into a CVD chamber. Optionally, purge gases flowing through outer housing 33 from inlet 43 to outlet 45 are also heated before injection. It is apparent from these figures that the active heating elements define a higher temperature zone through which gases flow prior to injection.

FIGS. 2C-D also illustrate optional element 35 that can be an active or a passive heating element. Preferably, this optional element is a passive element that serves to improve heat transfer from active elements 31 to gas-conducting conduit 49. In the case of conductive heating elements, passive element 35 can be a conductor that re-distributes heat to the inner portion of conduit 49. In the case of radiant heating elements, passive element 35 can be a black body structure, e.g., a rod comprising a black body material that re-radiates heat. In the case of inductive heating elements, passive element 35 can include electrically conductive structures that can absorb inductive energy so as to heat the gas-conducting conduits. With optional element 35, gases in gas-conducting conduit 49 can be heated both directly by the active heating elements and indirectly by passive element 35.

As described, thermalizing gas injectors of this embodiment, in particular injectors such as injector 51 of FIG. 2C, can be used to inject gaseous III-metal precursors into a CVD chamber for the processing of III-nitride compounds, in particular, for providing, a gaseous GaCl₃ precursor for GaN growth according to an HVPE process. In such an application, outer housing 33 gas-conducting and conduit 49 preferably comprise quartz. Passive element 35 is a solid or tubular, black body structure preferably comprising for example SiC, B₄C, AlN. Active heating element 31 comprises an electric heating jacket, e.g., clamp shell heater, which surrounds quartz outer housing 33 and is capable of heating to temperatures between 500 and 1000° C.

In operation, a GaCl₃ precursor enters the injector through inlet 39 with an incoming flow rate of usually on the order of several hundred sccm (standard cubic centimetres per minute) but possible up to 20-30 SLM (standard litres per minute) and exits through outlet 41 at temperatures preferably between 500 and 1000° C. An N₂ (or alternatively an N₂ and H₂ gas mixture) purge gas enters through inlet 43 with an incoming flow rate of approximately 1-5 SLM, maintains an overpressure in at least the interior of the outer housing, and exits through outlet 45. During its residence in the injector, the purge gas can also be heated.

### Further Preferred Embodiments of Thermalizing Gas Injectors

Preferred embodiments of the thermalizing gas injectors of this invention are now described that achieve increased gas residence times by configuring and sizing conduit structures to have gas flow paths that have cross-sections that are increased beyond those reasonably necessary for the intended gas flow velocities (in view of known principles of gas flow in conduits) and that have lengths that are at least as long as are reasonably necessary in the circumstances (in particular, in view of the physical layout of the chamber and associated equipment). Accordingly, the injectors of this embodiment can be useful for gases that enter into the CVD chamber at higher lower flow rates.

Since thermalizing gas injectors of this embodiment are useful for injecting thermalized gases at relatively higher flow rates, when used in connection with the growth of III-nitride compounds, the injectors of this embodiment are more preferred for use with N precursors, which typically enter at relatively higher flow rates, than for use with for III-metal precursors, which typically enter at relatively lower flow rates. However, the injectors of this embodiment can also be useful for gases that enter into the CVD chamber at relatively higher flow rates.

FIGS. 3A-B illustrate cross-section and transverse views, respectively, of an embodiment of the preferred thermalizing gas injectors. Conventional components include chamber housing 71, susceptor 69, growth substrate 67, and heating elements 60. Conduit structures 61 in this embodiment are arranged along both side sides of chamber housing 71 at the level of the upper surface of susceptor 69. Gas enters inlet ports 75, flows within the conduit structure in a longitudinal direction along the side walls, and exits through one or more outlet ports that direct gas in transverse streams 62 across the upper surface of susceptor 69 towards growth substrate 67. The conduit structures of this embodiment can also include other elements, in particular, outer housings. Conduit structures 61 are supported and held in the chamber by fixtures as known in the art, here by exemplary left and right support fixtures 73 having transversely-projecting prongs (or shelves) on which the gas conducting conduits are supported. A single, longer support fixture can extend each side wall of the CVD chamber, or alternately, multiple, shorter support fixtures can be positioned along each wall.

Conduit structures 61 can be actively heated, or passively heated, or both passively and actively heated. As with conduit structures 47 (of FIG. 2C), conduit structures 61 can also be actively heated by providing heat producing elements that are adjacent to at least a part of the gas-conducting portion. Preferably, conduit structures 61 are passively heated by being partially or entirely routed through and/or located within a heated environment, e.g., a heated CVD chamber. Also, passive heat transfer means are preferably associated with a portion (or all) of the conduit structure within the heated embodiment in order to improve heat transfer from the environment to the conduit structures. For example, such passive heat transfer means can comprise a black body material so as to absorb radiation from chamber heat lamps and re-radiate the absorbed heat to the conduit structure.

FIG. 3A illustrates passive heat transfer means that include one or more plates 65 that are supported above the conduit structures on the upper prongs of exemplary fixtures 73 and that extend across the CVD chamber (thus, also improving heat transfer to the susceptor). FIG. 3B illustrates multiple plates 65 positioned along the chamber so as to cover a substantial fraction of both gas conduits 61. Note that the gaps illustrated between plates 65 are for clarity only as normally these plates would be adjacent to each other. Alternatively, gas-conducting conduits 61 can be placed below plates 65, or plates 65 can extend only over only conduits 61 leaving the centre portion of the chamber exposed to the heat lamps.

Embodiments of the thermalizing gas injectors of this embodiment can inject gas with flow patterns different from the transverse flow patterns illustrated in FIGS. 3A-B. For example, FIG. 3C illustrates an embodiment in which gas-conducting conduits 61 are further configured to have outlet ports 76 that inject gases in longitudinal directions parallel to gas flows 63. Gas-conducting conduits 61 of FIG. 3C can be provided with further outlet ports, as in FIGS. 3A-B, for injecting gases in transverse flows. Gases can be injected in further flow patterns by providing appropriate outlet ports as will be apparent to one of ordinary skill in the art. Further embodiments can have only a single (left or right) gas-conducting conduit 61, can inject different second gases through each of the two illustrated gas-conducting conduits, and so forth.

Gas-conducting conduits of this embodiment are preferably fabricated from non-metallic materials that are capable of withstanding the high temperature, corrosive environments that develop in the interior of operating CVD reactors, e.g., HVPE reactors, and that have little or no interaction with precursor gases (especially, NH₃). A preferred such material comprises quartz. The black body plates preferably comprise materials with high emissivity values (close to unity) that are also capable of withstanding the high temperature, corrosive environments. Preferred such materials include AlN, SiC and B₄C (emissivity of 0.98, 0.92, and 0.92, respectively).

Further, the conduit structures and passive heat-transfer means are preferably sized and configured in view of a particular CVD chamber so that they can be arranged within that chamber so as not to interfere with the operation of, e.g., existing gas injectors, the susceptor, robot transfer means, and other associated components. Accordingly, different specific embodiments of the thermalizing gas injectors can be sized and configured to be arranged within differently sized and configured CVD chambers. For example, the thermalizing gas injectors illustrated in FIG. 3A-C have been sized and configured to be arranged in and cooperate with exemplary CVD chamber 1 of FIG. 1 in the manner now described.

First gases are injected in longitudinal flow 63 from injectors located at the upstream end (bottom in FIGS. 3B-C) of CVD chamber 71 and flow towards the susceptor. Although not specifically illustrated, the upstream injectors can be one or more of the injectors of the embodiments of FIGS. 2A-D. Second gases enter thermalizing gas injectors 61 of this embodiment through inlet ports 75 (external to the chamber 71), and flow within larger cross-section gas-conducting conduits 61. In the case of FIG. 3B, gases are injected through a plurality of outlet ports in a plurality of transverse streams flowing from both sidewalls towards the susceptor; and in the case of FIG. 3C, second gases are injected in two longitudinal streams flowing towards the susceptor. First and second gases meet and react over the susceptor, and spent gases exit through exhaust 64. Gas-conducting conduits 61 have been sized and configured to be arranged largely against the walls of chamber 71 so as not to interfere with the susceptor and other components.

Also in the case of FIG. 3B, specifics of the pattern of transverse flows 62 can be readily controlled by, e.g., differences in the sizes of the outlet ports. The larger cross-sections of diameters of gas-conducting conduits 61, although selected primarily to increase the residence time available for absorbing heat from the chamber interior, also permit the gas-conducting conduits to act as plenum chambers that approximately equalize gas pressures along the length of the conduits. For example, if the outlet ports are of similar sizes, transverse flows 62 can be longitudinally uniform, while if the outlet ports are of varying sizes, the transverse flows can be varying.

As described, thermalizing gas injectors of this embodiment, in particular injectors configured similarly to injector 61 of FIGS. 3A-C, can be used to provide gaseous N precursors into a CVD chamber for the processing of III-nitride compounds, in particular, for providing NH₃ for GaN growth according to an HVPE process. For such applications, gas-conducting conduits 61 can be sized from about 1 cm to 2 cm to 2.5 cm (and sizes there between), preferably comprise quartz, are supported within the chamber below (alternately, above) black body plates by fixtures 73 and have gas outlet 62 in the vicinity of the upper surface of the susceptor 69. The injectors preferably comprise quartz; and passive heating plates preferably comprise SiC, B₄C, AlN.

In operation, NH₃ enters the injector through inlet ports 75 at flow rates of 1-3 SLM. Only one or more than two such inlets could be utilized. The outlets of gas-conducting conduits 61 are located in the vicinity of susceptor 69. The NH₃ is heated by heat transferred from the heated interior of the CVD chamber and from SiC plates, both of which are heated by external lamp sources 60 situated above (and below) the quartz reactor housing 71. The NH₃ is preferably heated to a temperature of at least 600° C. prior to entry in the reaction chamber.

### Further Preferred Embodiments of Thermalizing Gas Injectors

Preferred embodiments of the thermalizing gas injectors of this invention are now described that, as well as achieving some degree of thermalization due to increased gas residence times, inject one or more gas streams in separate longitudinal gas flows with controlled transverse spatial distribution. In particular, the spatial distribution of at least one longitudinal gas stream is controlled to be transversely largely uniform across a width that is a significant portion of the diameter of the susceptor. Spatial distributions can also be controlled so that different gases do not prematurely mix, or change temperatures, or chemically interact. Injectors of this embodiment are referred to herein as ‘visor’-type injectors, or as ‘visor’ injectors, or as ‘visors’.

For example, in the case of growth of III-nitride compounds, visor injectors of this embodiment are useful for injecting III-precursor gases, N precursor gases, and purge gases. In particular, a visor injector can inject a precursor gases in a flow that is largely uniform in a transverse direction across a width that is a significant portion of the diameter of the susceptor. Thus, as the susceptor rotates, the growth substrates will have a largely uniform exposure to one of the precursors.

The term “significant portion of the susceptor”, when used herein in the above context, means that the gas flow (as injected and without significant spreading) can reach sufficient all portions of the susceptor so that all growth substrates carried thereon can be directly exposed to the gas flow. Since a susceptor usually rotates in operation, a longitudinal flow that extends across at least about one-half or more of the diameter of the susceptor will be largely uniform across a “significant portion of the susceptor”. More preferably, the flow extends across at least 65%, or 80%, or more of the diameter of the susceptor. Even more preferably, where chamber configuration permits, the flow extends substantially over all the susceptor diameter. The term “largely uniform” means that gas velocities with the flow vary by less than about 15%, or less than about 25%, or less than about 35%.

Visor-type injectors have outlet ports with cross sections chosen to form and encourage the exiting gas into the selected longitudinal distributions. In particular, a visor-type injector has at least one outlet port with a transverse width that is a significant portion of the susceptor, e.g., a transverse width that is about one-half or more of the susceptor diameter (a ‘wide’ outlet port). Other outlet ports (‘narrow’ outlet ports) are typically narrower in order to inject gases in more restricted flows (e.g., such as flows that would be injected through outlet ports configured similarly to outlet ports 76 of FIG. 3C). Conveniently and preferably, the vertical extents of wide outlet ports are less than (or much less than) that their transverse extents so that these outlets can be considered to have an, e.g., ‘flattened’ shape. Narrow outlet ports can have comparable transverse horizontal and vertical extents.

Outlet ports with larger transverse extent and smaller vertical extent can be conveniently accommodated by fabricating visor-type injectors from planar materials to have a planar shape. Outlet ports are preferably along a transverse edge of the planar shape, inlet ports can preferably be in the body or along an opposite transverse edge, and channels within the planar shape link inlet and outlet ports. Ports and channels (or grooves or cut-outs) can readily be fabricated in a first planar material by, e.g., etching, or machining, or ablating, or the like, and then by sealing the open channels with a second planar material. In other embodiments, channels can be fabricated formed in both the first and second planar materials, or within a single piece of a planar material. The planar materials preferably are able to withstand high temperature, chemically corrosive environments. A preferred such material is quartz; also black body materials such as AlN, SiC and B₄C can also be used.

Preferably, the channel linking the wide outlet port with its (one or more) inlet port has an increasing transverse extent, relatively narrow in the vicinity of the inlet port and increasing gradually until it matches the transverse extent of its outlet port. In various embodiments, such increasing channels can have different shapes with differently configured side walls. For example, such a channel with linear side walls can have a ‘wedge-like’ shape; alternatively with curvilinear sidewalls such a channel can have a ‘bell-like’ (convex sidewalls) or ‘nozzle-like’ shape (concave sidewalls). Generally, the channel shape and wall configuration can be selected according to the principles of fluid flow so that the flow injected through the outlet ports has desired characteristics, e.g., transverse uniformity. Channels linking narrow outlet ports to their inlet ports can have a largely constant cross sectional size.

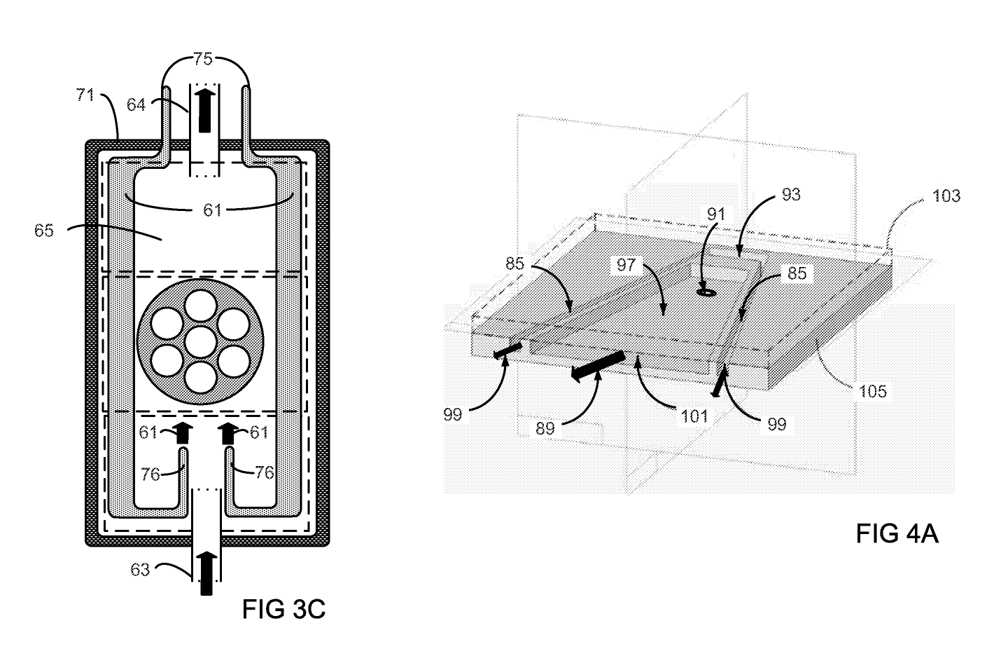

FIGS. 4A-C illustrate exemplary embodiments of visor-type injectors with exemplary configurations and arrangement of wide and narrow channels. FIG. 4A illustrates a visor injector with single wide, centrally-located outlet port 89 and two narrow outlet ports 99 located laterally to port 89. The solid arrows indicate gas flows that could be injected through these ports. Gas-conducting conduit 97 links inlet port 91 to outlet port 89 and has a generally wedge-like shape, extending from a narrower apex portion near the gas inlet 91 and linearly widening until it has a transverse extent equal to that of outlet port 89. Gas-conducting conduit 85 links inlet port 93 (not visible in this figure) to both outlet ports 99. This conduit is configured to have two arms ending in the outlet ports and a central portion linking the arms with the inlet port and sized to have a largely constant and relatively narrow cross-sectional size. This conduit lies outside of (and does not intersecting with) conduit 97. In this visor-type injector, the ports and channels are in bottom planar material 105 and are sealed by top planar material 103 both of which preferably comprise quartz.

FIG. 4B illustrates another exemplary visor-type injector with two relatively wide and laterally-located outlet ports 117 and 123 and a single relatively narrow and centrally-located outlet port. Gas conducting conduit 115 links inlet port 113 to outlet port 117 and has a shape with one straight side wall and one curvilinear side wall so that its transverse extent which increases more rapidly in the vicinity of inlet port 113 and more slowly in the vicinity of outlet port 117. Gas conducting conduit 121 which links inlet port 119 to outlet port 123 has a similar, but mirror-image shape. Visualized together, both these conduit have a form that can be considered ‘nozzle-like’. Gas-conducting conduit 127 links inlet port 125 with narrower outlet port 129 and has a largely constant cross sectional size.

FIG. 4C illustrates an end view of the embodiment of FIG. 4B, and demonstrates that a visor-type injector can be fabricated from heterogeneous materials. Here, in contrast to the embodiment of FIG. 2A, bottom planar material preferably comprises quartz, and top planar material preferably comprises a blackbody material.

Gases injected by visor injectors are preferably thermalized. In some embodiments, a visor-type injector can receive gases that have already been thermalized by prior passage through accessory injectors, e.g., injectors similar to the embodiments of FIGS. 2A-D or FIGS. 3A-C. In preferred embodiments, visor injectors are heated so as to thermalize, or to further thermalize, injected gases. Active heating using extra heating elements is less preferred (due to an injector's large transverse extent).

More preferably, visor injectors can be passively heated by being placed within a CVD chamber. Also, the residence times of gases injected through wide outlet ports can be increased due to decreased average flow velocities. In particular, as gases flow from a narrower part of a channel towards a wider part of the channel, their flow velocities decrease in comparison to gases injected through a channel of the same length but constant cross-sectional size. Further, passive, black body elements can be provided to increase heat transfer to a visor-type injector. Such black body elements can be part of the injector as illustrated in FIG. 4C. Also, similarly to other injectors of this invention, black body plates can be provided exterior but adjacent to a visor-type injector.

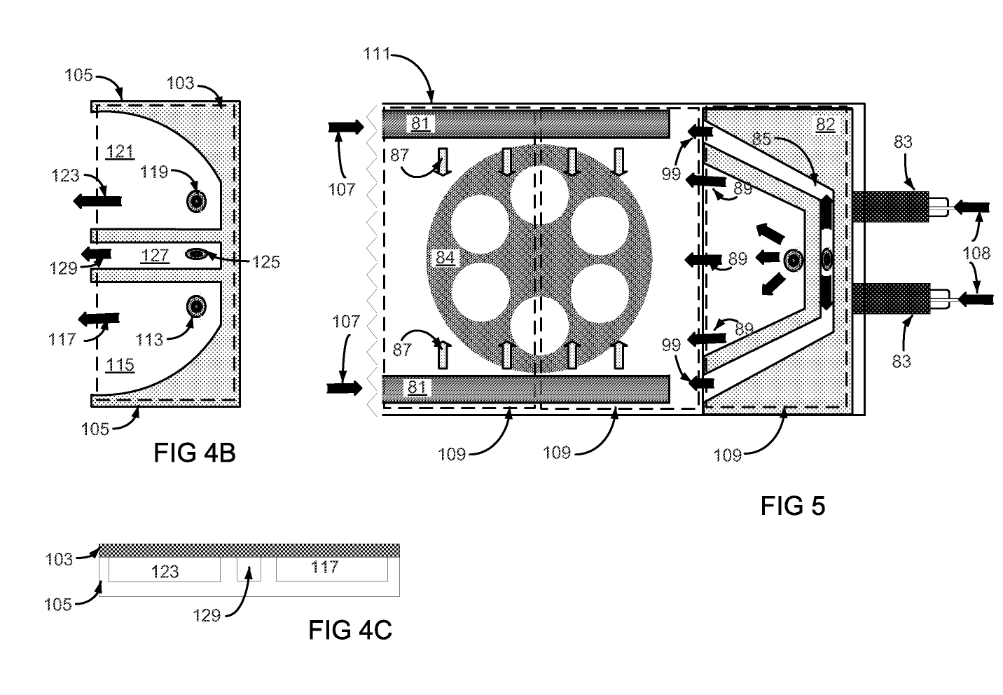

FIG. 5 illustrates a combination of an exemplary CVD chamber 111 with several of the thermalizing gas injectors of this invention, especially with visor-type injectors, cooperating to inject thermalized gases necessary for a certain CVD process. Here, visor-type injector 82, similar to the embodiment illustrated in FIG. 4A, is positioned in the upstream end of chamber 111, and injects first and second gas flows: first gas flow 89 is largely uniform in a transverse direction across a width that is a significant portion of the diameter of susceptor 84; and second gas flows 99 are lateral to the sides of flow 89 and of limited transverse extent.

Both the first and second gas flows are thermalized. Visor-type injector 82 receives gas flows 108 from external sources that have already been thermalized by passage through injectors 83 that are similar to the injector described with reference to FIGS. 2C-D. Injectors 83 are actively heated and are located largely external to chamber 111. Visor-type injector 82 is located within chamber 111 so it can further thermalize gases before injection. Optional black body plates 109 (indicated for clarity in dashed outline) are provided adjacent to injector 81 to improve heat transfer from the chamber to the visor-type injector.

The combination also includes injectors 81, similar to the injectors described with reference to FIGS. 3A-B, that are positioned lateral to susceptor 84 and adjacent to the side walls of chamber 111, and inject third gas flows 87 in a transverse direction from both chamber walls to and across susceptor 84. Transverse flows can have selected longitudinal distributions depending on the sizes of structures of the outlet ports from injectors 81. For example, the outlet ports can be configured and sized so that transverse flows 87 are also substantially uniform across a significant portion of the susceptor.

Injectors 81 are located within chamber 111 so gases can be thermalized before injection. Optional black body plates 109 are provided adjacent to injectors 81 to improve heat transfer from the chamber to the visor-type injector.

This combination of CVD chamber and the thermalizing gas injectors of this invention can be useful for, e.g., deposition of III-nitride materials, especially GaN according to an HVPE process. For GaN deposition, gas flows 89 could comprise gaseous GaCl₃, gas flows 87 could comprise NH₃, and gas flow 99 could comprises a purge gas such as H₂. Both precursor gases are injected from perpendicular directions in flows that are largely uniform in a transverse direction across a width that is a significant portion of the diameter of susceptor 84, and a purge gas can be injected for various purposes.

Different combinations of the injectors of this invention can be arranged to inject gas flows in the other selected patterns.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. The articles “a” or “an” or the like are also to be interpreted broadly and comprehensively as referring to both the singular and the plural. Moreover, any embodiments disclosed in the subject application are not to be taken as the only possible embodiments. Other embodiments will occur to those skilled in the art and are within the following claims.

1. A gas injector for injecting gases into a chemical vapour deposition (CVD) chamber comprising:
a gas-conducting conduit for conveying gases along a flow path through the conduit from a gas inlet port to one or more gas outlet ports;
one or more segments of the gas-conducting conduit where each segment is configured or sized to increase gas flow time through the conduit in comparison to the gas-conduit segments that are not so configured and sized; and
heating means arranged to heat the one or more segments of the gas-conducting conduit as the gases are conveyed therethrough.

2. The gas injector of claim 1 wherein the gas-conducting conduit comprises quartz.

3. The gas injector of claim 1 wherein the heating means further comprises a heated CVD chamber, and wherein the gas-conducting conduit is arranged so as to receive heat from the CVD chamber.

4. The gas injector of claim 1 wherein the heating means further comprises one or more heat-producing elements, and wherein the gas-conducting conduit is arranged so as to receive heat from the heat producing elements.

5. The gas injector of claim 1 wherein at least one selected segment is configured to have a longer gas flow path and an increased gas flow time at substantially similar gas flow velocities.

6. The gas injector of claim 5 wherein the gas-conducting conduit comprises gases flowing within that include a Group III-metal precursor for growth of a Group III-nitride semiconductor in the CVD chamber.

7. The injector of claim 5 wherein the selected segment(s) of the gas-conducting conduit comprises a spiral-like shape.

8. The injector of claim 7 further comprising an outer housing which encloses part or all of the spiral-shaped segment, and wherein the heating elements further comprise one or more clamp-shell heaters arranged exterior and adjacent to the outer housing.

9. The gas injector of claim 7 wherein the heating means further comprise a black body element located within the outer housing but external to the spiral-shaped segment for enhancing heat transfer from the exterior heaters to the gas-conducting conduit.

10. The gas injector of claim 7 wherein the outer housing further comprises a gas inlet port and a gas outlet port, and is further configured and sized so that gases can flow through the inner housing from the inlet port to the and outlet port.

11. The gas injector of claim 1 wherein at least one selected segment is configured to have a gas flow path with a larger cross-section size and increased gas flow times at smaller gas flow velocities.

12. The gas injector of claim 11 wherein the gas-conducting conduit comprises gases flowing within that include a nitrogen precursor for growth of a Group III-nitride semiconductor in the CVD chamber.

13. The gas injector of claim 11 wherein the larger segment has a substantially constant, larger, cross section size.

14. The gas injector of claim 11 wherein the heating means further comprises a heated CVD chamber, and wherein the larger segment is configured and sized to be arranged interior to the CVD chamber, along a longitudinal interior wall of the chamber, with a plurality of outlet ports arranged so that gas flows are directed from the lateral wall towards the center of the chamber.

15. The gas injector of claim 11 wherein the cross-section size of the larger segment grows larger from an apex section towards a base section where the segment opens into a CVD chamber.

16. The gas injector of claim 15 wherein gases flowing within gas-conducting conduit comprise a Group III-metal precursor for growth of a Group III-nitride semiconductor in the CVD chamber.

17. The gas injector of claim 15 wherein the larger segment comprises a wedge-shaped channel within a planar structure, the wedge-shaped channel having a relatively narrower apex with a gas inlet port and a relatively broader base with a first outlet that opens into the CVD chamber, and the planar structure being shorter in a vertical direction and larger in a transverse direction.

18. The gas injector of claim 17 further comprising at least one second gas-conducting channel that does not intersect the wedge-shaped channel, that has a second gas inlet port, that has a substantially constant cross-section size, and that has one or more second outlets that opens into a CVD chamber laterally to the outlet of the wedge-shaped channel.

19. The gas injector of claim 17 wherein the heating means further comprises a heated CVD chamber, and wherein the planar structure is configured and sized to be arranged interior to the CVD chamber along the upstream transverse wall and is arranged to direct gas flows in a downstream direction.

20. A chemical vapour deposition (CVD) system comprising:
a CVD chamber having upstream and downstream transverse walls and two longer longitudinal walls; and
at least one gas injector according to claim 17 for injecting gases into the CVD chamber.

21. The CVD system of claim 20 further comprising:
a susceptor having a growth surface and being located within the CVD chamber;
wherein the at least one gas injector includes a first gas injector located within the chamber adjacent to the upstream transverse wall and being configured and arranged so that:
a first outlet port adjacent to the susceptor and injects first gases in a longitudinal flow that extends across a portion of the susceptor growth surface, and
two second outlet ports inject third gases in two longitudinal flows lateral to each edge of the first gas flow.

22. The CVD system of claim 20 further comprising a further gas injector configured so that first gases flow from the outlet port of the further injector to the inlet ports of the first injector.

23. The CVD system of claim 20 further comprising two second gas injectors located within the chamber, each second gas configured along the interior of a longitudinal chamber wall and arranged so that the plurality of outlet ports direct gas flows from the lateral wall towards the center of the chamber.

24. The CVD system of claim 23 further comprising one or more black body plates for enhancing heat transfer from heating elements external to the CVD chamber to the two second gas injectors.

25. The CVD system of claim 23 wherein the first, second and third gases comprise precursor gases and a purge gas for a CVD process.

26. A method for injecting gases into a chemical vapour deposition (CVD) chamber comprising:
conveying gases along a segmented flow path from a gas inlet port to one or more gas outlet ports, with each segment configured or sized to increase gas flow time in comparison to the segments that are not so configured and sized; and
heating the one or more segments as the gases are conveyed therethrough.

27. The method of claim 26 wherein at least one selected segment provides a gas flow path with a larger cross-section size and increased gas flow times at smaller gas flow velocities with the gases flowing therein including a nitrogen precursor for growth of a Group III-nitride semiconductor in the chamber.

28. The method of claim 27, wherein at least one other segment has a cross-sectional size that grows larger from an apex section towards a base section where the segment opens into the chamber, with the gases flowing therein including a Group III-metal precursor for growth of a Group III-nitride semiconductor in the chamber.

29. The method of claim 28 wherein the chamber includes therein a susceptor having a growth surface and the gases of Group III-metal and nitrogen precursors are heated and directed toward the susceptor growth surface for growth of a Group III-nitride semiconductor thereon.

30. The method of claim 29 wherein the gases react at a temperature approximately greater than 930° C. to facilitate growth of Group III-nitride semiconductor on the susceptor growth surface while minimizing formation of undesirable precursor complexes.
